(19) United States
(12) Patent Application Publication
(10) Pub. No.: US 2018/0284597 A1
(43) Pub. Date: Oct. 4, 2018

(54) ETCH KERNEL DEFINITION FOR ETCH MODELING

(71) Applicant: GLOBALFOUNDRIES INC., GRAND CAYMAN (KY)

(72) Inventors: Francois WEISBUCH, Dresden (DE); Andrey LUTICH, Dresden (DE)

(73) Assignee: GLOBALFOUNDRIES INC., GRAND CAYMAN (KY)

(21) Appl. No.: 15/475,475

(22) Filed: Mar. 31, 2017

(51) Int. Cl. G03F 1/36; G06F 17/50

(52) U.S. Cl. CPC G03F 1/36; G06F 17/5081

(57) ABSTRACT

Geometrically-defined kernels are applied along each point of a lithographic contour to derive etch parameters that can be used to characterize the etch response of any structure. The etch parameters can be further used to construct an accurate etch model. The approach provides a more detailed definition of the etch parameter space and results in better guidance for selecting optimal calibration structures.

### BACKGROUND

The present application relates generally to semiconductor device manufacture, and more specifically to an optical proximity correction (OPC) methodology for forming a lithography mask.

Advances in integrated circuit (IC) materials and design have yielded generations of ICs where successive generations have smaller and more complex circuits. As ICs evolve, the functional density (i.e., the number of interconnected devices per unit area) has generally increased and the critical dimension (i.e., the minimum feature size) has decreased. While dimensional scaling improves performance, increases production efficiency, and lowers costs, it has also increased the complexity of processing and manufacturing. Such processing and manufacturing typically include photolithography, which is used to transfer a pattern onto a substrate.

Optical proximity correction (OPC) is a photolithography enhancement technique used to compensate for image errors due to diffraction or process effects that arise principally from the limitations of light to maintain edge placement fidelity between an originating mask pattern and the transferred (e.g., etched) image on a semiconductor wafer. Typical errors include line widths that are narrower or wider than designed and/or distortions such as rounded corners, which if not corrected may alter the reliability and performance of the device being fabricated.

Optical proximity correction endeavors to decrease or eliminate these errors by redesigning the initial mask such that the image reproduced on the substrate represents the intent of the designer (and not necessarily an exact replica of the image formed on the mask). Corrections at the mask level may be accomplished by using pre-computed tables or by using models that dynamically simulate the final pattern and thereby drive the repositioning of mask features.

### SUMMARY

Notwithstanding recent developments, there is a need for improved methods of semiconductor device manufacture and feature patterning. The present application relates to an optical proximity correction (OPC) method of preparing data for forming a mask used to define etch features on a semiconductor substrate.

In various embodiments, optical and photoresist models can be used to simulate the profile printed in a layer of resist. Effective device patterning, in turn, may result from accurately predicting and controlling the contours that are transferred from the printed layer of resist into the semiconductor substrate after etching the substrate.

An etch model typically includes an initial lithographic (photoresist) contour, and computes for each point of the contour a bias, or shift, that maps the pre-etch shape onto a post-etch contour. The generation of a set of bias data enables designers to prepare a lithography mask for patterning a desired structure with precision and accuracy. As will be appreciated, the bias vectors are typically not constant around a given contour, and can be strongly dependent on the local geometry.

Disclosed are a set of functions, or kernels, for producing an accurate and stable OPC etch model. The kernels are based on geometric considerations that are adapted to the etch process, and can be used to provide a mask solution.

In accordance with embodiments of the present application, a method of preparing layout data for optical proximity correction (OPC) comprises receiving data representing structures of a desired layout to be created photo-lithographically and designating contours of the layout representing data that are to be biased prior to application of OPC. For at least one contour to be biased, a geometric kernel such as internal kernel, external kernel, curvature-based kernel or a Gaussian-based kernel is calculated and applied to a model that correlates the kernel to an etch OPC correction. The contour to be biased is then biased using the OPC correction. An etch OPC correction refers to the dimensional changes associated with the transfer from lithography to etch.

A further method comprises designating a lithographic contour that is to be biased and calculating a kernel for the contour, where the kernel is selected from the group consisting of an internal kernel, an external kernel, a curvature-based kernel and a Gaussian-based kernel. The calculated kernel is applied to a model that correlates the kernel to an etch OPC correction, and lithographic contour to be biased is biased using the OPC correction.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a top-down plan view scanning electron microscope (SEM) micrograph showing a patterned photoresist layer over a semiconductor substrate together with associated lithographic contours;

FIG. 2 is a schematic diagram showing the etch contours corresponding to the lithographic contours of FIG. 1;

FIG. 3 shows the lithographic and etch contours of FIGS. 1 and 2 for an exemplary structure, and the bias vectors between the contours at select points;

FIGS. 4A-4D are geometric representations of various contour-shifting kernels according to certain embodiments;

FIGS. 5A-5D show the effect of the kernels on example patterned structures including plural adjacent features;

FIGS. 6A-C are schematic diagrams depicting the parameterization for various etch kernels; and

FIG. 7 is a schematic illustration of a computer system and computer program product adapted to perform the presently-disclosed method.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Disclosed is a method for incorporating geometrically-derived constraints into a model-based optical proximity correction (OPC) software tool for use in an optical lithography system to provide accurate correction of device shapes in a photomask for IC manufacture.

The photolithography process involves duplicating desired circuit patterns onto semiconductor wafers to achieve an overall desired circuit performance The desired circuit patterns are commonly represented as opaque, complete and semi-transparent regions on a template typically referred to as a photomask. In photolithography, patterns on the photomask template are projected onto a photoresist-coated substrate (e.g., semiconductor substrate) by way of optical imaging through an exposure system.

The photolithographic process used to form a physical layer on a substrate includes designing one or more mask shape layouts used to transfer the circuit design shapes to the substrate. Optical proximity correction (OPC) is a process used to refine the shapes on the mask so that the transfer of mask patterns to the physical layer reproduces the desired circuit design shapes with optimal fidelity.

In accordance with various embodiments, optical proximity correction algorithms pre-correct shapes formed on a photomask by segmenting the shape edges and shifting the position of the segments by minor amounts. OPC software emulates the physical and optical effects that are principally responsible for the non-fidelity of mask shapes printed on the substrate.

In the correction phase of OPC, the mask shapes are iteratively modified so that the shapes printed on the wafer match the desired shape. This method automatically distorts existing mask shapes to achieve the target dimensions on the wafer.

Optical proximity correction is commonly used to compensate for image errors resulting from diffraction or process effects. The diffraction of light in optical lithography systems, for instance, is an obstacle to feature size scaling. The implementation of OPC derives at least in part from the limitations of light to maintain edge placement (e.g., etched image) fidelity of an original design after processing. OPC endeavors to achieve a mask design that generates a printed structure that matches the design intent, including feature size and placement.

During photolithography, projected images commonly appear with irregularities such as line widths that are narrower or wider than designed. Other distortions such as rounded corners may be driven by the resolution of the optical imaging tool. Such distortions, if not corrected, may significantly alter the performance and reliability of the intended device. Optical proximity correction addresses these potential errors by moving edges or adding extra features to the pattern written on a photomask. The OPC objective function (E) incorporates the process variation information.

The adjustments to the mask layout may be rule-based and obtained from pre-computed data based on, for example, the width and spacing between features, or model-based using dynamic calculations to simulate the final pattern and thereby define an initial pattern that produces the intended solution.

Disclosed is a suite of etch kernels that can efficiently represent etch effects at any point along a lithographic contour. The etch kernels can be incorporated into a model-based OPC methodology to improve patterning quality and enhance manufacturing yield.

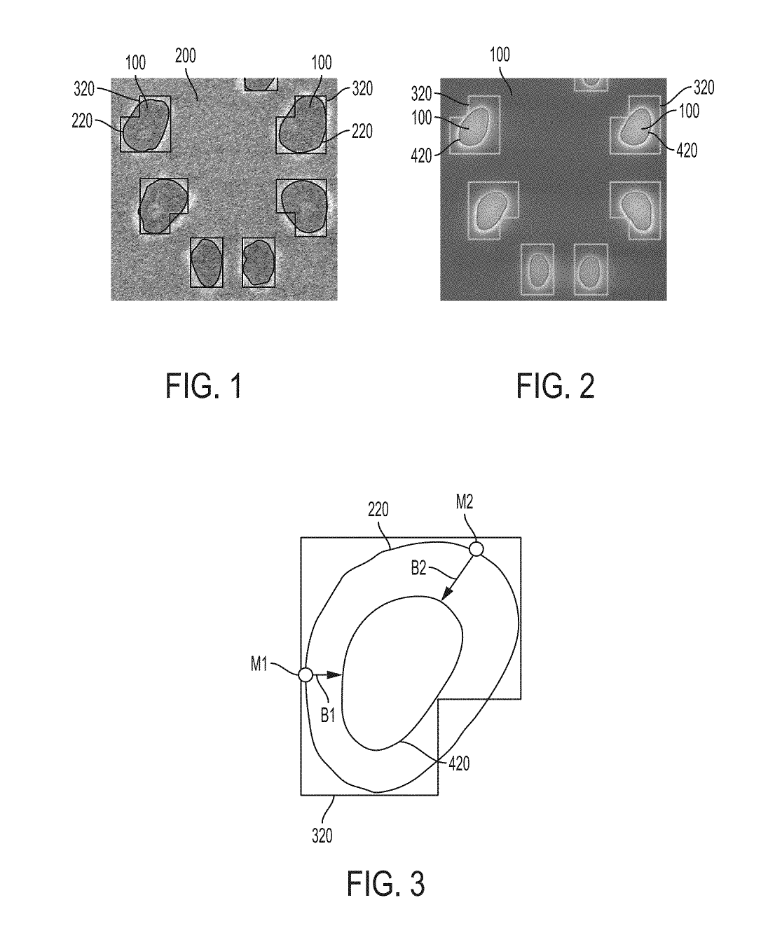

Referring to FIG. 1, shown is a top-down plan view scanning electron microscope (SEM) image of a patterned photoresist layer 200 disposed over a semiconductor substrate 100. The photoresist may be disposed directly over a surface of the substrate 100 or over an intervening layer such as an interlayer dielectric or conductive layer (not shown). The layer of photoresist material 200 may be formed by a deposition process such as, for example, spin-on coating. The photoresist may include a positive-tone photoresist composition, a negative-tone photoresist composition, or a hybrid-tone photoresist composition.

The deposited photoresist is subjected to a pattern of irradiation, and the exposed photoresist material is developed utilizing a conventional resist developer. The pattern provided by the patterned photoresist material is thereafter transferred into the substrate 100 or a layer overlying the substrate utilizing at least one pattern transfer etching process.

The pattern transfer etching process is typically an anisotropic etch. In certain embodiments, a dry etching process such as, for example, reactive ion etching (RIE) can be used. In other embodiments, a wet chemical etchant can be used. In still further embodiments, a combination of dry etching and wet etching can be used. The photoresist layer may be removed during the etching step or following the etching step using a conventional process such as ashing, e.g., using an oxygen-containing plasma.

Referring still to FIG. 1, lithographic contours 220 are superimposed over the micrograph to delineate the profile, i.e., shape and dimension, of the pattern formed in the layer of photoresist. Each lithographic contour 220 traces the patterned edge in the layer of photoresist. Reference contours 320 are also shown, which define the general shape of the patterns formed in the layer of photoresist 200. The reference contours 320 may, for example, correspond to the designer's intent.

Referring to FIG. 2, following an etching step, a further SEM micrograph shows etch contours 420 superimposed on the etched substrate. Each etch contour 420 corresponds to a respective one of the lithographic contours of FIG. 1. However, due to phenomena related to under- or over-etching, for example, the etch contours 420 may have a shape that is similar to, but dimensions different from, the lithographic contours 220, or a shape that is different from (and hence dimensions that are different from) the lithographic contours.

Referring to FIG. 3, shown is the relative size and shape of an exemplary pair of lithographic and etch contours 220, 420 relative to the corresponding reference contour 320. In various embodiments, the lithographic contours 220 as well as the etch contours 420 are intended to have the size and dimensions of the reference contours 320.

In the instant example, the etch contour 420 is displaced laterally from the lithographic contour 220 due to under-etching. Accordingly, also shown in FIG. 3 are bias vectors (b1, b2), which are drawn normal to the lithographic contour 220 (i.e., perpendicular to a line tangent to each point M1, M2). The bias vectors define the displacement between the lithographic contour 220 and the etch contour 420. It will be appreciated that the bias vectors in the illustrated embodiment are not uniform, and that the magnitude of the bias vectors (b) at each point (M) varies with position. In various embodiments, the magnitude of the bias vector varies as a function of position and the attendant environment.

In the illustrated embodiment of FIG. 3, the substrate is effectively under-etched with respect to the lithographic contour 220 and the reference contour 320, i.e., the etched shape is smaller than the designer's intent such that the etch contour 420 is predominantly inscribed within the reference contour 320. Although not illustrated, an alternate result may include an etch contour that is over etched, such that the etch contour is circumscribed, at least in part, with respect to the boundary of the corresponding reference contour.

As disclosed herein, an etch model derives and implements a comprehensive set of bias vector data, which are used to calculate an etch contour from a starting lithographic contour. According to various embodiments, an OPC method includes a predictive etch model that uses one or more geometrically-defined kernels to enable an accurate determination of the lithographic profile that is needed in order to generate a desired etch profile. The model may be used to reliably extrapolate and predict contours different from those used during an initial calibration. In an example method, geometric parameters are assessed (computed) for each point around a lithographic contour. As used herein, a “kernel” is a function that can be applied to an image through convolution in order to generate certain effects.

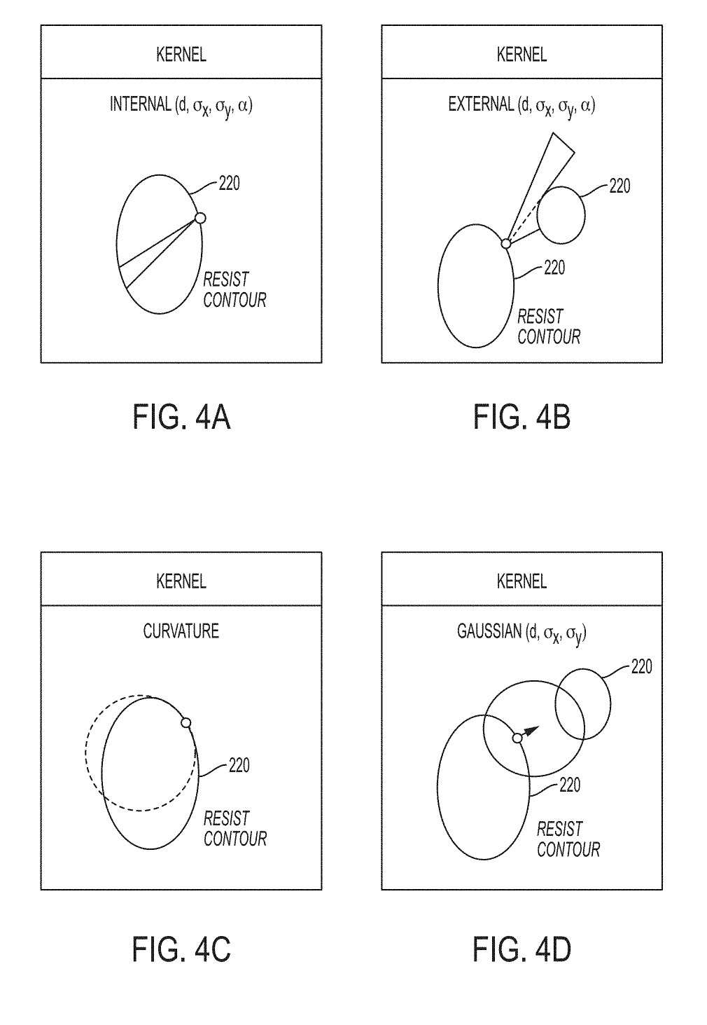

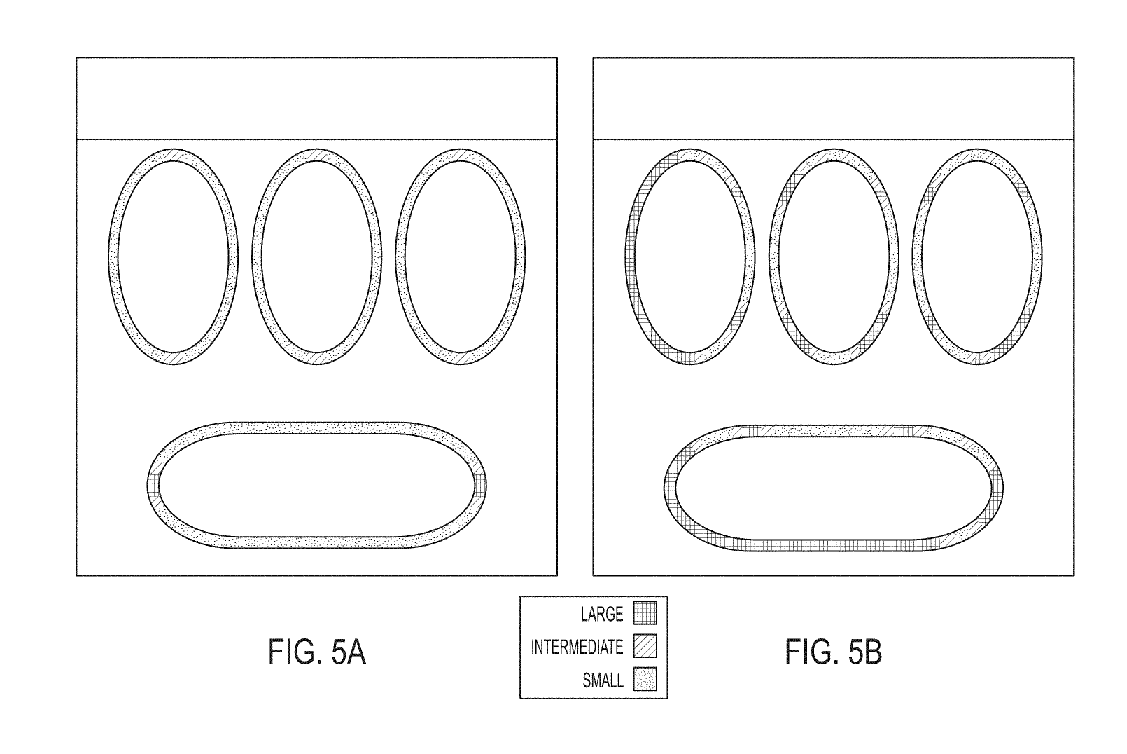

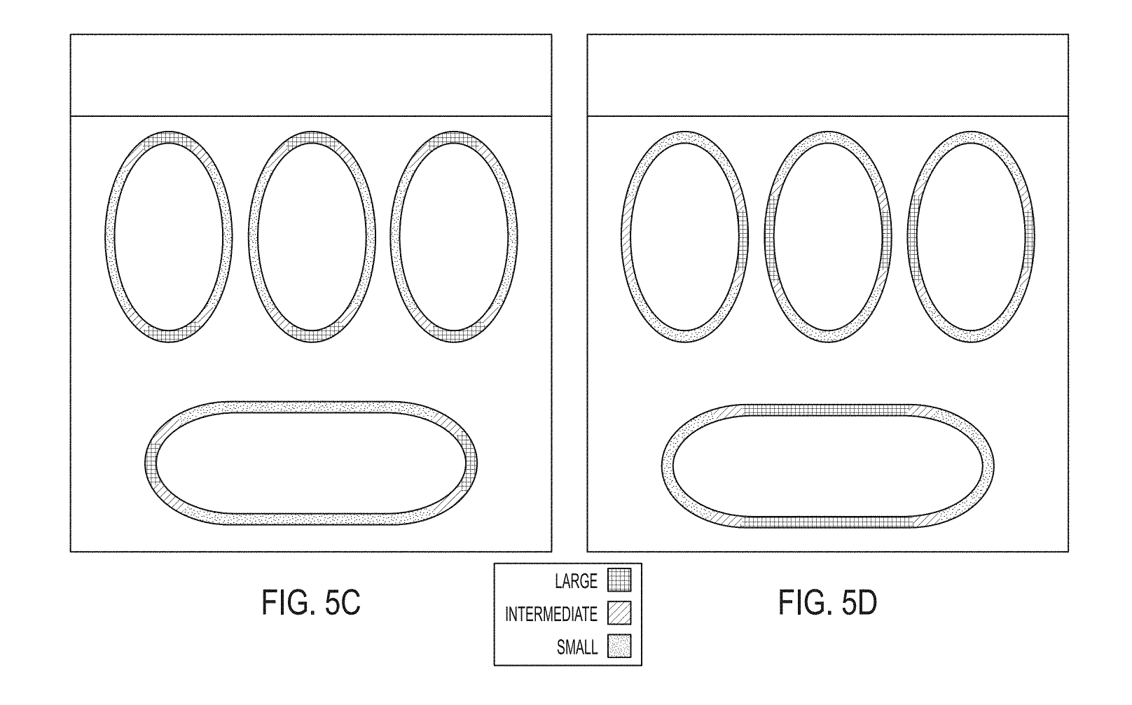

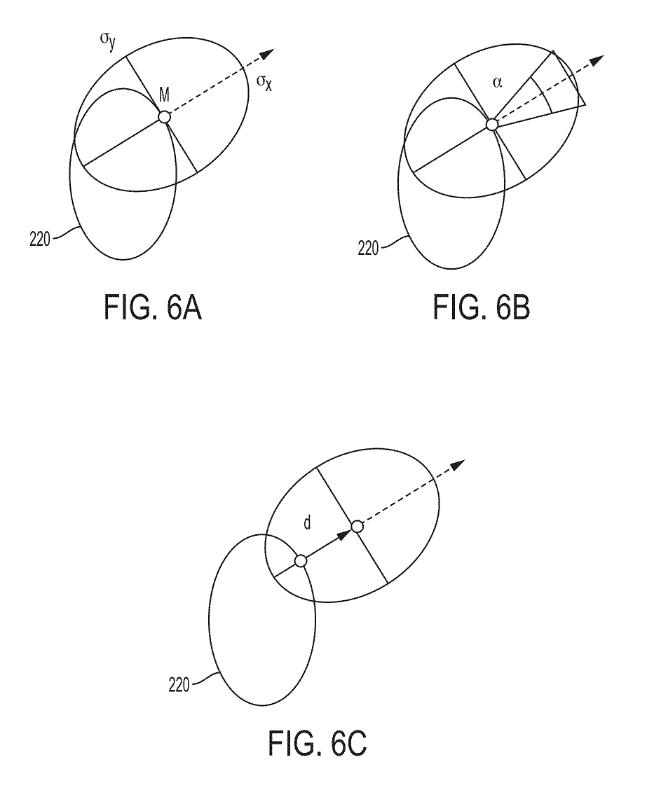

Starting from a simulated lithographic contour, each point (M) along the contour can be characterized based on the geometry of the contour adjacent to that point, or by a specific kernel evaluated at the point. Thus, in various embodiments, mapping of a point on a lithographic contour to a corresponding etch contour considers the local environment of that point. The etch kernels described herein can be characterized by their geometric import, and may include internal, external, curvature, and Gaussian-based kernels, which are shown schematically in FIGS. 4A-D, respectively. FIGS. 5A-D show the application of the various kernels to a geometry comprising plural elliptical contours. The kernels may be applied independently or in combination using, for example, a polynomial expression with suitably weighted coefficients.

Referring to FIG. 4A, in various embodiments, an internal kernel senses the influence on etch effects of the internal local density of a pattern at a point M along a selected pattern contour. An internal kernel represents the internal normal distance from one point on the contour to another point on that contour.

By way of example, for an elliptically-shaped contour, the pair of points located along the major axis of the ellipse are characterized by a maximum internal kernel, while the pair of points located along the minor axis of the ellipse are characterized by a minimum internal kernel. The effect is illustrated qualitatively in FIG. 5A, which shows a hypothetical pattern of elliptically-shaped lithographic contours and the evaluation of the kernel at each point along the contours. The value of the kernel is mapped qualitatively as regions of large, intermediate and small values to illustrate the effect. An internal kernel may model, for example, the thickness of a layer of photoresist. An internal kernel is anisotropic because sensing is effected perpendicular to the contour.

Referring to FIG. 4B, in various embodiments, an external kernel senses the influence on etch effects of neighboring patterns relative to a given point M along the pattern contour. An external kernel represents the external normal distance from one point on a first contour to a point on a second, adjacent contour. As with an internal kernel, because sensing is principally perpendicular to the contour, an external kernel is highly anisotropic. In FIG. 5B, as in FIG. 5A, the value of the external kernel for a pattern of elliptically-shaped lithographic contours is mapped qualitatively as regions of large, intermediate and small values to illustrate the effect.

According to various embodiments, the internal and external kernels can consider data strictly normal to each point (M) along the contour. Such a kernel may be characterized by a conical angle α, where α=0°. Alternatively, the angle α for an internal kernel or an external kernel may be greater than 0°, e.g., 0<α≤45°, such that the kernel considers and incorporates data from a broader area. The internal or external distance where α>0° may be a simple arithmetic average or may be calculated as a weighted average.

Referring to FIG. 4C, a curvature-based kernel senses the influence of the curvature of a pattern evaluated at a given point along the pattern contour on the etch effects. In various embodiments, the curvature is a scalar quantity that represents the amount by which the contour at a point (M) deviates from being straight, as in the case of a line. In FIG. 5C, the value of the curvature-derived kernel is shown schematically for the hypothetical pattern of elliptically-shaped lithographic contours.

As shown schematically in FIGS. 4D and 5D, a Gaussian kernel, or the combination of multiple Gaussian kernels, captures the long range density effects of one or more neighboring patterns with respect to a given point M along the selected pattern contour. Such a kernel is poorly anisotropic.

Parameterization of the kernels is illustrated with reference to FIG. 6. Referring to FIG. 6A, a kernel may comprise a Gaussian function defined by orthogonal standard deviations (σₓ, σ_{y}) or, as shown schematically in FIG. 6B, such a Gaussian function truncated by a cone of angle α (i.e., a kernel defined by σₓ, σ_{y} and α). In various embodiments, angle α may range from 0 to 45°, e.g., 0, 2, 5, 10, 15, 20, 25, 30, 35, 40 or 45°, including ranges between any of the foregoing values. A non-truncated Gaussian function will consider inputs from all directions, while a truncated Gaussian function will consider only inputs from within the specified window. Such functions can be convolved with the resist contour to compute the value of the kernel at point M. As shown in FIG. 6C, the function can be shifted by a distance (d) relative to the normal of the resist contour.

The internal and external kernels can be convolved with any function, e.g., a Gaussian function, to modulate their behavior. For example, an external kernel defined over an angle (α) can be convolved with a Gaussian to emphasize or deemphasize the contribution to the kernel of features within a sub-angle (α1) of (α). The instant kernels are not limited to convolution with Gaussian functions, however. As will be appreciated by those skilled in the art, other 2D functions, including Laguerrian or sinusoidal functions may be used.

The proposed kernels (internal, external, curvature, Gaussian) may be chosen to precisely capture the geometric effects of the lithographic contours while exhibiting little or no redundancy, i.e. little or no correlation. The behavior of the kernels may be defined with only a few parameters that add more degrees of freedom to adapt to specific etch process or pattern dimensions.

In contrast to existing models that refer to inefficient kernels that are either too coarse or overly symmetric to adequately capture the spatial sensitivity of the lithography-etch bias on the geometry of the structure contours, the disclosed kernels are not limited to symmetric Gaussian or coarse visibility kernels.

In accordance with embodiments of the present application, in performing a correction to a lithographic contour, the optical proximity correction (OPC) is directed to consider additional constraints, including the geometry of the environment proximate to the contour. In various embodiments, the method involves applying a bias that is proportional to the value of the kernel to deduce an etch contour based only on the lithographic contour.

In certain embodiments, each iteration of the OPC performs a simulation and determines if the lithographic contour satisfies an edge placement error (EPE), which is a quantitative representation of the deviation of the edges of a simulated mask image with respect to the edges of the target image. Typically, EPE tolerances are expressed as geometric rules or constraints on the image shapes relative to shapes on the same physical layer. If the image does not remain within tolerance or the allowable EPE, the segment is iteratively moved forward or backward until all of the simulated image edges are located within an accepted tolerance of the location of the target image edges. Eventually, the final corrected mask layout is outputted.

Before OPC bias values are calculated for contours in a desired layout pattern, the OPC model may be calibrated to a known OPC solution. Test layout data, including feature patterns and dimensions likely to be used in the actual desired layout, are analyzed with an OPC tool to determine how the feature edges should be moved to print as desired. The test layout data may be analyzed to determine the kernels at select points in the test data. A mathematical analysis may be performed to correlate the various kernels to the known OPC correction values.

Embodiments of the present disclosure are used in optical lithography to correct for distortions on a photomask having patterns of circuit design features in order to achieve an accurate projection of the patterns onto a photoresist coated substrate. Model-based OPC is performed in which edge placement error (EPE) constrains are modified to include geometric effects on the pattern transfer etch. The method has been demonstrated to improve patterning quality, and correspondingly enhance manufacturing yield as well as device performance and reliability by addressing a known failure mechanism.

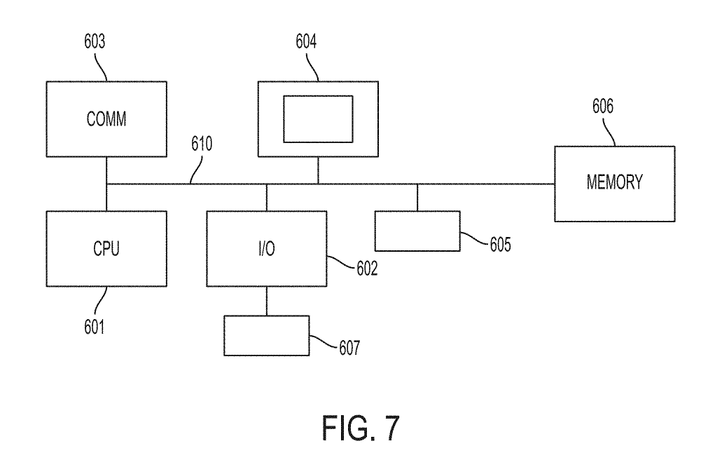

Embodiments of present method may be implemented by a networked or stand-alone digital computer or computer system that executes a sequence of computer instructions, as shown schematically in FIG. 7. Components of an exemplary computer or computer system include a central processing unit (CPU) 601, an input/output (I/O) device 602 (such as a keyboard, mouse, compact disk (CD) drive, etc.), a controller 603, a display device 604, a storage device 605 capable of reading and/or writing computer readable code, and memory 606. The foregoing are typically connected, e.g., by a bus or a communications network 610.

Various embodiments may be implemented as a computer program product stored on a computer readable medium 1507, such as a tape or CD, or on the storage device 1505. Alternatively the instructions may be received by the computer system over a wired or wireless communication link.

The computer -an execute the instructions to read a desired layout pattern or portion thereof and compute bias amounts for at least some edge fragments in the layout in accordance with the techniques described above.

The disclosed method, which enhances etch model capability, incorporates flexible, sensitive and geometrically-specific kernels that provide better definition of the etch parameter space, and provide better guidance for selecting suitable calibration structures.

As used herein, the singular forms “a,” “an” and “the” include plural referents unless the context clearly dictates otherwise. Thus, for example, reference to a “kernel” includes examples having two or more such “kernels” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a function that comprises an internal kernel and a Gaussian kernel include embodiments where a function consists essentially of an internal kernel and a Gaussian kernel and embodiments where a function consists of an internal kernel and a Gaussian kernel.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A method of preparing layout data for optical proximity correction (OPC), comprising:
receiving data representing structures of a desired layout to be created photo-lithographically;
designating a contour of the layout representing data that is to be biased prior to application of OPC;
for the contour to be biased, calculating a kernel selected from the group consisting of an internal kernel, an external kernel, a curvature-based kernel and a Gaussian-based kernel;
applying the calculated kernel to a model that correlates the kernel to an OPC correction; and
manufacturing a photolithography mask using the OPC correction.

2. The method of claim 1, wherein the model comprises a calibrated model.

3. The method of claim 1, wherein the contour comprises a lithographic contour.

4. The method of claim 1, wherein the calculated kernel is convolved with a Gaussian function.

5. The method of claim 1, wherein the calculated kernel is truncated by an angle (α), where 0<α≤45°.

6. The method of claim 1, wherein the calculated kernel comprises a Gaussian function truncated by an angle (α), where 0<α≤45°.

7. The method of claim 1, wherein the calculated kernel comprises an internal kernel convolved with a Gaussian or an external kernel convolved with a Gaussian.

8. The method of claim 1, wherein the calculated kernel comprises an internal kernel truncated by an angle (α), where 0<α≤45°.

9. The method of claim 1, wherein the calculated kernel comprises an external kernel truncated by an angle (α), where 0<α≤45°.

10. The method of claim 1, wherein the internal kernel represents an internal normal distance from a point on the contour to another point on the contour.

11. The method of claim 1, wherein the external kernel represents an external normal distance from a point on the contour to another point on another contour.

12. The method of claim 1, wherein the curvature-based kernel represents a curvature of the contour.

13. A method of preparing layout data for optical proximity correction (OPC), comprising:
designating a lithographic contour that is to be biased;
calculating a kernel for the contour, wherein the kernel is selected from the group consisting of an internal kernel, an external kernel, a curvature-based kernel and a Gaussian-based kernel;
applying the calculated kernel to a model that correlates the kernel to an OPC correction; and
manufacturing a photolithography mask using the OPC correction.

14. The method of claim 13, wherein the internal kernel represents an internal normal distance from a point on the contour to another point on the contour.

15. The method of claim 13, wherein the external kernel represents an external normal distance from a point on the contour to another point on another contour.

16. The method of claim 13, wherein the curvature-based kernel represents a curvature of the contour.

17. A computer storage media, including a sequence of instructions stored thereon that are executable by a computer to perform the method of claim 1.
